(19) United States
(12) Patent Application Publication
(10) Pub. No.: US 2012/0309206 A1
(43) Pub. Date: Dec. 6, 2012

(54) Stoichiometry Control Of Transition Metal Oxides In Thin Films

(75) Inventor: David Thompson, San Jose, CA (US)

(73) Assignee: Applied Materials, Inc., Santa Clara, CA (US)

(21) Appl. No.: 13/452,389

(22) Filed: Apr. 20, 2012

Related U.S. Application Data
(60) Provisional application No. 61/478,156, filed on Apr. 22, 2011.

(51) Int. Cl. H01L 21/3105; H01L 21/30

(52) U.S. Cl. 438/778; 438/758; 257/E21.211; 257/E21.241

(57) ABSTRACT

One aspect of the invention relates to a method for deposition of a film having a predetermined film composition. The method comprises: in a deposition chamber: providing a substrate at a fixed temperature; depositing a film; flowing a mixture of two gases, wherein the ratio of the two gases is selected such that the mixture has a redox potential to provide a predetermined film composition. In some embodiments, depositing a film occurs via an atomic layer deposition process or chemical vapor deposition process. Methods for chemical vapor deposition of a metal or lanthanide oxide layer are provided featuring a mixture of oxidizing and reducing gases is flowed over the transition metal oxide or lanthanide oxide layer. The mixture of gases has an oxidation potential selected to produce a layer having a desired stoichiometry of a deposited film.

### CROSS REFERENCE TO RELATED APPLICATIONS

This patent application claims the benefit of pending U.S. Provisional Patent Application Ser. No. 61/478,156, filed Apr. 22, 2011, the contents of which are incorporated in their entirety herein by reference.

### TECHNICAL FIELD

The present invention relates to the use of gas mixtures for controlling oxidation and reduction potential in semiconductor processes.

### BACKGROUND

Deposition of thin films on a substrate surface is an important process in a variety of industries, including semiconductor processing, diffusion barrier coatings and dielectrics for magnetic read/write heads. In the semiconductor industry, in particular, miniaturization requires atomic level control of thin film deposition to produce conformal coatings on high aspect structures. One method for deposition of thin films is chemical vapor deposition (CVD) in which a gas phase chemical precursor molecule and a reactant gas are reacted on and/or above a temperature-controlled surface to form a thin film. The reactive species, energy, rate of chemical supply, substrate temperature and substrate itself contribute to determining the properties of the film. In a typical CVD process, the reactants are introduced into the reactor in gas phase and activated by heat, plasma or other means. The reactive species are then adsorbed onto the substrate surface, where they may undergo chemical reactions or react with other incoming species to form a solid film. Reaction by-products are desorbed from the substrate surface and removed or purged from the reactor.

A variation of chemical vapor deposition for deposition of thin films is atomic layer deposition (ALD), which employs sequential, self-limiting surface reactions to form layers of precise thickness controlled at the Angstrom or monolayer level. Most ALD processes are based on binary reaction sequences which deposit a binary compound film. Each of the two surface reactions occurs sequentially and because they are self-limiting a thin film can be deposited with atomic level control. Because the surface reactions are sequential, the two gas phase reactants are not in contact and possible gas phase reactions that may form and deposit particles are limited. The self-limiting nature of the surface reactions also allows the reaction to be driven to completion during every reaction cycle, resulting in films that are continuous and pinhole-free.

Metal oxide films incorporating transition metals and lanthanides are used in semiconductor applications including high K gate dielectric films, active materials for ferroelectric memories, thin film battery cathodes and materials in silicon based light emitting devices. However, the ability to control the specific composition of the metal oxide deposited layer can be limited. Many metal-oxygen condensed phase systems employ metal oxides that are known to be stable at different oxidation potentials and have well-defined stoichiometric phases. For these materials it is generally possible to consistently obtain a desired metal oxide once an oxidation potential threshold is exceeded and equilibrium is reached. However, for other systems in which there are a variety of metal oxides that vary in stoichiometry (e.g., MO₂, M₄O₉, M₃O₄, M₂O₃) it may be necessary to keep the oxidation potential within a narrowly defined range to produce the desired condensed phase.

Control of the composition of the condensed phase is even more difficult when the metal oxide phase exhibits non-stoichiometry. In this case, any variation in oxidation potential of the gas phase at a constant temperature will impact the composition of the condensed phase. Although this problem has been addressed by selecting precursors more likely to yield the desired film, it is not a useful approach in high temperature depositions as the choice of precursor is better made by considering its thermal stability, vapor pressure, deliverability and the presence of constituents that may contaminate the film.

Many deposition processes utilize post deposition anneal environments with either extreme oxidizing or reducing capability. This is sufficient to produce the desired composition of the condensed phase provided it cannot be “over-reduced” or “over-oxidized.” There is therefore a need for CVD and ALD processes in which the oxidation/reduction potential of the deposition environment can be better controlled to produce transition metal oxide thin films on substrate surfaces which have consistent compositions, even at very low oxygen pressures. This need is particularly acute in the field of deposition of nonstoichiometric metal oxides, such as transition metal oxides. The present invention addresses this need.

### SUMMARY

One aspect of the invention relates to a method for deposition of a film having a predetermined film composition. The method comprises: in a deposition chamber: providing a substrate at a fixed temperature; depositing a film; flowing a mixture of two gases, wherein the ratio of the two gases is selected such that the mixture has a redox potential to provide a predetermined film composition. The ratio of the two gases can be varied to yield variable redox potentials. In some embodiments, depositing a film occurs via an atomic layer deposition process or chemical vapor deposition process. The deposited film may include various structures in a semiconductor, including, but not limited to a diffusion barrier coating or dielectric for magnetic read/write heads. In some embodiments, the gas mixture may comprise a third gas. In some variants, the deposited layer comprises a metal oxide or lanthanide oxide.

There are several variants in how the film is deposited and gas mixture is flowed. For example, in one embodiment, the flowing the mixture of two gases occurs during deposition or between deposition cycles. In another embodiment, flowing the mixture of two gases is a post-deposition process. In a further embodiment, the post-deposition process occurs in a second chamber. An example of such a post-deposition process includes, but is not limited to, an annealing process. Examples of such gas mixtures include, but are not limited to H₂/H₂O and CO/CO₂.

In one or more embodiments, the temperature is ramped. This can affect the composition of the film.

Another aspect of the invention provides a method for chemical vapor deposition of a metal or lanthanide oxide layer comprising, in a deposition chamber: contacting a surface of a substrate with a vapor phase metal or lanthanide chemical precursor and a reactant gas such that a transition metal oxide or lanthanide oxide layer is formed on the surface; removing unreacted precursor, reactant gas and reaction by-products from the deposition chamber, and; flowing a mixture of oxidizing and reducing gases over the transition metal oxide or lanthanide oxide layer, wherein the mixture of oxidizing and reducing gases has an oxidation potential selected to produce a layer having a desired stoichiometry of transition metal oxide or lanthanide oxide.

In one embodiment, the present invention provides methods for controlling the composition of nonstoichiometric transition metal oxide and lanthanide oxide thin films produced by CVD or ALD, wherein a desired composition of the oxide film is obtained by introducing a gas phase chemical precursor and a reactant gas into a deposition environment, depositing the transition metal oxide or lanthanide oxide film on a substrate surface in the deposition environment, and subsequently exposing the deposited oxide film to a mixture of oxidizing and reducing gases wherein the gas mixture has a preselected oxidation potential expressed as a function of the temperature of the deposition environment and the ratio of the components of the gas mixture, thereby obtaining a transition metal oxide or lanthanide oxide film having a desired stoichiometry. The oxidizing/reducing gas mixture may also be referred to as a buffered gas phase. In a CVD process the reactant gas is introduced into the deposition environment before, after or at the same time as the chemical precursor, with the understanding that both components are present in the deposition environment at the same time during the deposition reaction. In an ALD process the chemical precursor is introduced into the deposition environment and allowed to react with the substrate surface before the reactant gas is introduced in a separate sequential reaction step.

In another embodiment, the present invention provides methods for controlling the composition of nonstoichiometric transition metal oxide and lanthanide oxide thin films produced by CVD or ALD, wherein a chemical precursor is introduced into a deposition environment and a reactant gas is introduced into the deposition environment before, after or at the same time as the chemical precursor, forming a condensed phase film. Following completion of the CVD or ALD deposition process a buffered gas phase is flowed over the condensed phase film, the buffered gas phase having an oxidation potential selected to produce the desired stoichiometry of the condensed phase film. In specific embodiments the buffered gas phase may be a combination of H₂/H₂O, CO/CO₂ or any other mixture of oxidizing and reducing gases that has an oxidation potential expressed as a function of temperature and the ratio of two or more gas components in the system.

In a specific aspect of the invention, the process of any of the foregoing embodiments employs a transition metal precursor compound comprising, for example, any of the Group 3-12 elements of the periodic table. Of these, compounds comprising iron, copper, silver, gold, palladium, platinum, rhodium, iridium, tungsten, titanium, zirconium, hafnium, vanadium, niobium, tantalum, chromium, molybdenum, aluminum, manganese and ruthenium are of particular interest as chemical precursors for transition metal oxide thin films in CVD and ALD processes and may be used in the methods of the invention. Transition metal precursor compounds useful in the invention include, but are not limited to, tetramethyl heptanedionato (TMHD) derivatives as is known in the art.

In an alternative specific aspect of the invention, the process of any the foregoing embodiments employs a lanthanide precursor compound comprising, for example, cerium or any other element in the lanthanide series of the periodic table (atomic numbers 58-71). Lanthanide precursor compounds useful in the invention include, but are not limited to, tetramethyl heptanedionato derivatives as is known in the art. In a specific embodiment, the lanthanide precursor is Ce(TMHD)₄.

Yet another embodiment is directed to a modification of any of the foregoing embodiments wherein the oxidizing/reducing gas phase for producing the desired stoichiometric composition of the transition metal oxide or lanthanide oxide thin film is CO/CO₂ or H₂/H₂O.

A further embodiment is directed to a modification of any of the foregoing embodiments wherein the reactant gas for deposition of the transition metal oxide or lanthanide oxide thin film is oxygen. A specific example of this embodiment includes deposition of CeO₂ thin films, wherein the precursor is Ce(TMHD)₄ and the reactant gas is O₂.

In yet a further embodiment of the invention, the appropriate composition of the buffering gas phase to obtain a desired transition metal oxide stoichiometry in the condensed phase at a selected temperature in any of the foregoing embodiments may be determined by use of an Ellingham diagram.

In a further embodiment of the invention, the deposited transition metal oxide or lanthanide oxide layer of any of the foregoing embodiments is exposed to the buffering gas phase for a time and at a temperature sufficient to obtain the desired stoichiometry of the transition metal oxide in the layer.

### BRIEF DESCRIPTION OF THE DRAWINGS

FIG. 1 is an Ellingham Diagram.

FIG. 2 is a CVD phase diagram for Ce(TMHD)₄ and O₂.

### DETAILED DESCRIPTION

Before describing several exemplary embodiments of the invention, it is to be understood that the invention is not limited to the details of construction or process steps set forth in the following description. The invention is capable of other embodiments and of being practiced or being carried out in various ways.

Reference throughout this specification to “one embodiment,” “certain embodiments,” “one or more embodiments” or “an embodiment” means that a particular feature, structure, material, or characteristic described in connection with the embodiment is included in at least one embodiment of the invention. Thus, the appearances of the phrases such as “in one or more embodiments,” “in certain embodiments,” “in one embodiment” or “in an embodiment” in various places throughout this specification are not necessarily referring to the same embodiment of the invention. Furthermore, the particular features, structures, materials, or characteristics may be combined in any suitable manner in one or more embodiments.

The present invention provides the advantage of being able to control the oxidation potential of a CVD or ALD process through thermodynamic equilibria, independently of deposition chamber pressure. The methods can be used to generate oxidation potentials that may not be obtainable using existing engineering controls. For example, achieving a specific oxidation potential (e.g., 10⁻³⁵ atmospheres of O₂) may be limited by the capabilities of equipment such as the vacuum pump. In such cases, however, the desired effective potential can be achieved using a ratio of oxidizing and reducing gases as described herein. In addition, the present invention makes it possible to obtain a specific composition of the deposited layer within a non-stoichiometric phase regime or to obtain a challenging phase bounded by two other phases with neighboring compositions. This can be used either in depositing a film or after the film is already deposited to modify the composition of the film.

Accordingly, one aspect of the invention relates to a method for deposition of a film having a predetermined film composition. The method comprises: in a deposition chamber: providing a substrate at a fixed temperature; depositing a film; flowing a mixture of two gases, wherein the ratio of the two gases is selected such that the mixture has a redox potential to provide a predetermined film composition. In some embodiments, depositing a film occurs via an atomic layer deposition process or chemical vapor deposition process. The deposited film may include various structures in a semiconductor, including, but not limited to a diffusion barrier coating or dielectric for magnetic read/write heads. In some embodiments, the gas mixture may comprise a third gas. In some variants, the deposited layer comprises a metal oxide or lanthanide oxide.

There are several variants in how the film is deposited and gas mixture is flowed. For example, in one embodiment, the flowing the mixture of two gases occurs during deposition or between deposition cycles. In another embodiment, flowing the mixture of two gases is a post-deposition process. In a further embodiment, the post-deposition process occurs in a second chamber. Examples of such a post-deposition process include, but is not limited to, an annealing process. Examples of such gas mixtures include, but are not limited to H₂/H₂O and CO/CO₂.

In one or more embodiments, the temperature is ramped. This can affect the composition of the film.

In another aspect, the invention provides a method for chemical vapor deposition of a metal or lanthanide oxide layer comprising, in a deposition chamber: contacting a surface of a substrate with a vapor phase metal or lanthanide chemical precursor and a reactant gas such that a transition metal oxide or lanthanide oxide layer is formed on the surface; removing unreacted precursor, reactant gas and reaction by-products from the deposition chamber, and; flowing a mixture of oxidizing and reducing gases over the transition metal oxide or lanthanide oxide layer, wherein the mixture of oxidizing and reducing gases has an oxidation potential selected to produce a layer having a desired stoichiometry of transition metal oxide or lanthanide oxide.

For example, the condensed phase stability diagram for Ce(TMHD)₄ with oxygen at 0.5 Torr shows six phases, with phases such as Ce₁₈O₃₁ bounded by two other phases. To obtain a desired phase using the processes described herein the CO/CO₂ is kept constant at the appropriate ratio to obtain the oxygen to precursor ratio indicated by the phase stability diagram at a selected reaction temperature. This creates a maximum oxidation potential. The time to completion drives the reaction to the desired composition (i.e., all compositions of lower oxidation state are oxidized to the selected maximum). The practitioner only needs to determine the time required for the reaction when temperature and CO/CO₂ ratio are kept constant.

A further advantage of the present invention is the ability to maintain a desired partial pressure of O₂ during a CVD or ALD deposition process, thereby keeping the oxidation potential of the deposition environment constant. This reduces variability in the composition of the deposited transition metal oxide which would otherwise occur due to variation in O₂ partial pressure during the process. The ratio of gases in the buffering gas phase of the invention is independent of pressure, thus maintaining consistency during periods of O₂ partial pressure variation.

The ability to control the oxidation state of the deposited transition metal oxide further allows the use of a greater variety of precursor materials for deposition in CVD and ALD processes.

Using cerium oxides as an example, FIG. 3 of M. Zinkevich, et al. (Solid State Ionics. 177 (2006) 989-1001) illustrates how variation in equilibrium oxygen pressures (P_{O2}) over condensed phases results in variability of the condensed phase composition at a selected temperature. In general, a ratio of two gases in a buffering gas phase can be calculated from such a diagram by selecting the curve corresponding to the desired reaction temperature, reading the corresponding PO2 from the left axis and calculating the gas ratio necessary to obtain the corresponding PO2. For example, if the reaction temperature is 1296° K and the desired atomic ratio of O/Ce in the composition is 1.8, the PO2 read from the intersection of the temperature curve with the left axis is 10⁻¹⁸ mole O₂. If the buffering gas phase is CO/CO₂, the equilibrium between CO+½ O₂ and CO₂ can be reduced to the ratio of CO/CO₂ which provides a 10⁻¹⁸ mole partial pressure of O₂.

As a general rule, to obtain an increased partial pressure of O₂, CO₂ is increased relative to CO (either by increasing CO₂ or decreasing CO). To obtain a decreased partial pressure of O₂, CO is increased relative to CO₂ (either by increasing CO or decreasing CO₂).

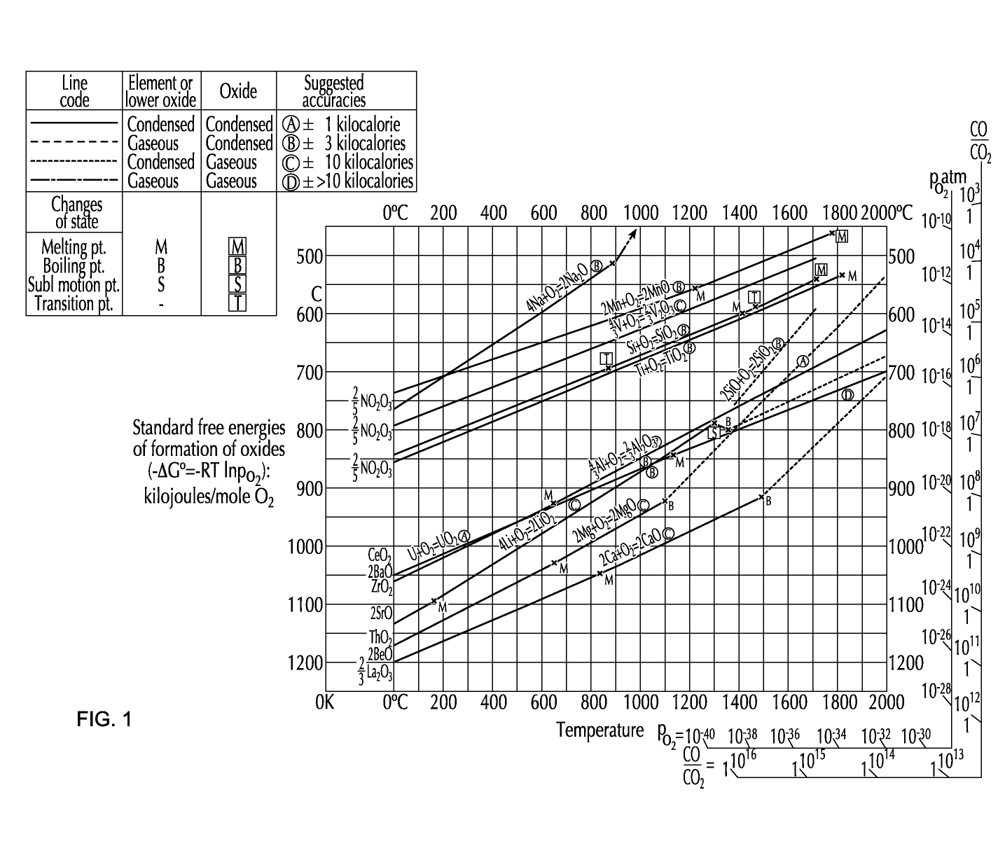

The Ellingham diagram illustrated in FIG. 1 of this application can be used to solve the equilibrium equation to obtain the appropriate CO/CO₂ ratio for a buffering gas phase at a selected reaction temperature for a selected transition metal oxide. The Ellingham diagram is a plot of AG versus temperature. FIG. 1 is shown for metals reacting to form oxides. The oxygen partial pressure is taken as 1 atmosphere, and all of the reactions are normalized to consume one mole of O₂. To use the Ellingham diagram to determine the ratio of CO/CO₂ that will be able to reduce the oxide to metal at a given temperature, the following steps are followed:
1. Locate the desired reaction temperature at the top of the diagram;
2. Identify the curve corresponding to the oxidation line of interest.
3. Determine the point where the oxidation line intersects the temperature line.
4. Draw a straight line from the “C” on the left axis of the diagram through the intersection of the oxidation line and the temperature line and continue it through the CO/CO₂ ratio scale.
5. Read the CO/CO₂ ratio from the scale where the line intersects it.

This is the minimum ratio that will reduce the selected oxide. Ratios of CO/CO₂ above the minimum ratio will result in a stable oxide composition. Ratios below the minimum will favor the reactants.

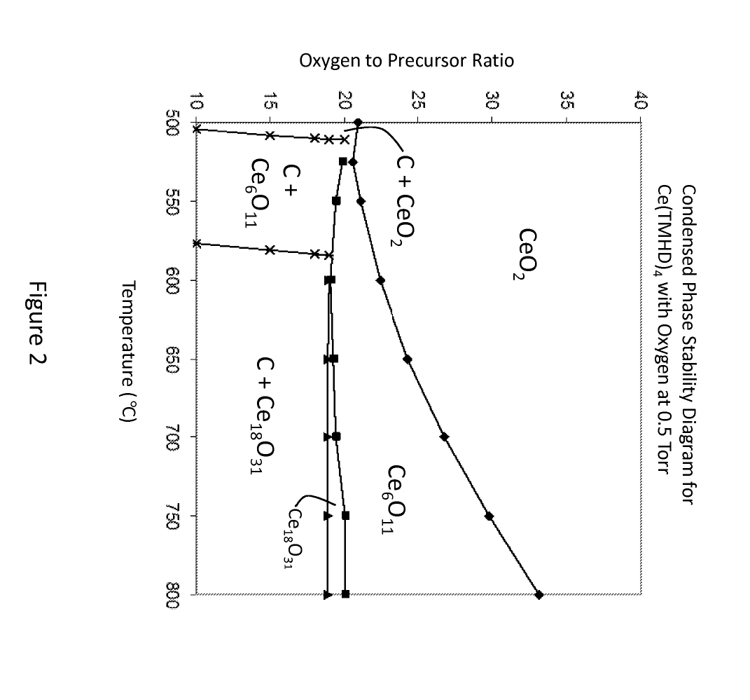

A specific example is illustrated in FIG. 2, which is a CVD phase diagram for Ce(TMHD)₄ and O₂. In CVD oxygen and the precursor are present in a constant ratio. Following deposition of the condensed phase, a CO/CO₂ buffering gas phase at a specified constant ratio is flowed over the condensed phase to create an environment having a desired oxidation potential to produce the desired stoichiometry in the condensed phase. For example, if maximum oxidation of the condensed phase is desired, the CO/CO₂ ratio is selected as described above to produce an oxidizing gas mixture and the reaction is run to completion. As shown in FIG. 2, a variety of condensed phase compositions can be obtained during CVD, each shown by a separate curve. Exposure of the condensed phase to an oxidizing buffering gas phase selected to produce a condensed phase having a particular oxidation state converts all less oxidized condensed phase species to the selected oxidized form over time. That is, by selecting the CO/CO₂ ratio such that the oxidizing potential corresponds to the desired oxidation state of the condensed phase, exposure of the initial condensed phase to the buffering gas phase will eventually convert all species to the selected oxidation state. If the reaction temperature and the CO/CO₂ ratio are held constant, it is only necessary to determine experimentally the length of time required for complete conversion to the desired species.

The methods of the invention may be employed in any process for deposition of thin films on substrate surfaces, including semiconductor processing, diffusion barrier coatings and dielectrics for magnetic read/write heads. CVD and ALD processes are presented as illustrative examples, but the methods are not so limited. To obtain a specific transition metal oxide film composition via a CVD process, the chemical precursor is first introduced into the deposition chamber with the reactant gas as is known in the art. In an ALD process the chemical precursor and the reactant gas are introduced in sequential steps of the reaction. Once the conventional CVD or ALD process has finished, a buffering gas phase comprising two or more gases and having an oxidation potential corresponding to the desired stoichiometry of the condensed phase is flowed over the deposited film at an appropriate temperature and for a sufficient time to obtain the desired condensed phase. The buffering gas phase may include a gas which is the same as the reactant gas used in the deposition portion of the process. The buffering gas phase may also comprise more than two gases, for example, three or four different oxidizing and reducing gases.

In specific examples, the above process is used to deposit thin films of transition metal oxide or lanthanide oxide having a desired stoichiometry on a substrate surface to produce high K gate dielectric films, active materials for ferroelectric memories, thin film battery cathodes, silicon based light emitting devices, semiconductors, diffusion barrier coatings and dielectrics for magnetic read/write heads.

Although the invention herein has been described with reference to particular embodiments, it is to be understood that these embodiments are merely illustrative of the principles and applications of the present invention. It will be apparent to those skilled in the art that various modifications and variations can be made to the method and apparatus of the present invention without departing from the spirit and scope of the invention. Thus, it is intended that the present invention include modifications and variations that are within the scope of the appended claims and their equivalents.

What is claimed is:

1. A method for deposition of a film having a predetermined film composition, the method comprising: in a deposition chamber:
providing a substrate at a fixed temperature;
depositing a film;
flowing a mixture of two gases, wherein the ratio of the two gases is selected such that the mixture has a redox potential to provide a predetermined film composition.

2. The method of claim 1, wherein the flowing the mixture of two gases occurs during deposition or between deposition cycles.

3. The method of claim 1, wherein flowing the mixture of two gases is a post-deposition process.

4. The method of claim 3, wherein the post-deposition process occurs in a second chamber.

5. The method of claim 4, wherein the post-deposition process in an annealing process.

6. The method of claim 1, wherein the temperature is ramped.

7. The method of claim 1, wherein the mixture of two gases is selected from the group consisting of H₂/H₂O and CO/CO₂.

8. The method of claim 1, wherein depositing a film occurs via an atomic layer deposition process or chemical vapor deposition process.

9. The method of claim 8, wherein the deposited film is a diffusion barrier coating or dielectric for magnetic read/write heads.

10. The method of claim 1, further comprising a third gas in the gas mixture.

11. The method of claim 1, wherein the deposited film comprises a metal oxide or lanthanide oxide.

12. A method for chemical vapor deposition of a transition metal oxide layer comprising, in a deposition chamber:
a) contacting a surface of a substrate with a vapor phase metal or lanthanide chemical precursor and a reactant gas such that a transition metal oxide or lanthanide oxide layer is formed on the surface;
b) removing unreacted precursor, reactant gas and reaction by-products from the deposition chamber, and;
c) flowing a mixture of oxidizing and reducing gases over the transition metal oxide or lanthanide oxide layer, wherein the mixture of oxidizing and reducing gases has an oxidation potential selected to produce a layer having a desired stoichiometry of transition metal oxide or lanthanide oxide.

13. The method of claim 12, wherein the chemical precursor is a lanthanide precursor.

14. The method of claim 12, wherein the chemical precursor is a transition metal precursor.

15. The method of claim 12, wherein the mixture of oxidizing and reducing gases comprises CO/CO₂ or H₂/H₂O.

16. The method of claim 13, wherein the lanthanide precursor is Ce(TMHD)₄ and the reactant gas is O₂.

17. The method of claim 16, wherein the lanthanide oxide layer after flowing the mixture of oxidizing and reducing gases consists essentially of CeO₂.

18. The method of claim 12, wherein the mixture of oxidizing and reducing gases comprises three or more gases.

19. The method of claim 18, wherein the deposited transition metal oxide or lanthanide oxide layer is exposed to the mixture of oxidizing and reducing gases for a period of time sufficient for completion of an oxidation reaction.

20. A method for chemical vapor deposition of a transition metal oxide layer comprising, in a deposition chamber:
a) contacting a surface of a substrate with a vapor phase lanthanide chemical precursor comprising Ce(TMHD)₄ and a reactant gas comprising O₂ such that a lanthanide oxide layer is formed on the surface;
b) removing unreacted precursor, reactant gas and reaction by-products from the deposition chamber, and;
c) flowing a mixture of oxidizing and reducing gases comprising CO/CO₂ or H₂/H₂O over the transition metal oxide or lanthanide oxide layer, wherein the mixture of oxidizing and reducing gases has an oxidation potential selected to produce a layer having a desired stoichiometry of transition metal oxide or lanthanide oxide,
wherein the lanthanide oxide layer after flowing the mixture of oxidizing and reducing gases consists essentially of CeO₂.
